(19) United States
(12) Patent Application Publication
(10) Pub. No.: US 2024/0280406 A1
(43) Pub. Date: Aug. 22, 2024

(54) HYPERSPECTRAL IMAGE SENSOR AND SYSTEM EMPLOYING THE SAME

(71) Applicant: KOREA ADVANCED INSTITUTE OF SCIENCE AND TECHNOLOGY, Daejeon (KR)

(72) Inventors: Mooseok JANG, Daejeon (KR); Gookho Song, Daejeon (KR); Dong-Gu Lee, Baejeon (KR)

(73) Assignee: KOREA ADVANCED INSTITUTE OF SCIENCE AND TECHNOLOGY, Daejeon (KR)

(21) Appl. No.: 18/443,488

(22) Filed: Feb. 16, 2024

(30) Foreign Application Priority Data
Feb. 17, 2023 (KR) 10-2023-0021605

(51) Int. Cl. G01J 3/28; G01J 3/45

(52) U.S. Cl. CPC G01J 3/2823; G01J 3/45; G01J 2003/284

(57) ABSTRACT

Provided are a hyperspectral image sensor and a hyperspectral imaging system including the hyperspectral image sensor. The hyperspectral image sensor includes a light-receiving sensor that is pixelated, and a plurality of metasurfaces that are arranged in front of the light-receiving sensor apart from each other in a stacking direction, and each have an array of meta-atoms. At least one of the plurality of metasurfaces is a random metasurface in which the meta-atoms are disorderly arranged, and a speckle pattern is formed on a sensing surface of the light-receiving sensor by the plurality of metasurfaces.

### CROSS-REFERENCE TO RELATED APPLICATION

This application is based on and claims priority under 35 U.S.C. § 119 to Korean Patent Application No. 10-2023-0021605, filed on Feb. 17, 2023, in the Korean Intellectual Property Office, the disclosure of which is incorporated by reference herein in its entirety.

### BACKGROUND

### 1. Field

The disclosure relates to a hyperspectral image sensor and a hyperspectral imaging system including the hyperspectral image sensor.

This research was conducted with the support of the Samsung Future Technology Development Project (Task Number: SRFC-IT2002-03).

### 2. Description of the Related Art

Hyperspectral imaging (HSI) technology enables simultaneous acquisition of image information and spectral information from a target. Hyperspectral image generation methods are generally classified into a scanning type and a non-scanning snapshot type. A scanning method may be implemented by combining a spectroscopic image sensor with a scanning device. A non-scanning snapshot method may perform a measurement by using different filters directly on image pixels.

Scanning-type hyperspectral measurement methods are advantageous in obtaining high-resolution hyperspectral images, but require a long measurement time and make it difficult to miniaturize equipment due to scanning. Non-scanning-type snapshot methods guarantee a short measurement time like general cameras and are advantageous in equipment miniaturization, but limit the space of image pixels to guarantee spectral resolution and thus result in poor image resolution.

### SUMMARY

Provided is a hyperspectral image sensor capable of acquiring high-resolution hyperspectral images and a hyperspectral imaging system including the hyperspectral image sensor.

Additional aspects will be set forth in part in the description which follows and, in part, will be apparent from the description, or may be learned by practice of the presented embodiments of the disclosure.

According to an aspect of the disclosure, a hyperspectral image sensor includes a light-receiving sensor that is pixelated, and a plurality of metasurfaces that are arranged in front of the light-receiving sensor apart from each other in a stacking direction and each have an array of meta-atoms. At least one of the plurality of metasurfaces is a random metasurface in which the meta-atoms are arranged to exhibit a disordered phase delay distribution, and a speckle pattern is formed on a sensing surface of the light-receiving sensor by the plurality of metasurfaces.

In the random metasurface, the meta-atoms may be arranged in a disordered size distribution to exhibit a random phase map information for incident plane wave, and the random phase map may be defined as phase delay values according to coordinates in a spatial domain.

The meta-atoms of the random metasurface may have identical heights and irregular sizes.

The meta-atoms of the random metasurface may be regularly positioned.

The meta-atoms of the random metasurface may be regularly positioned and may have irregular sizes.

At least one of a number of the plurality of metasurfaces and a distance between the metasurfaces may be determined such that sizes of at least some of speckles of the speckle pattern may be greater than a pixel size of the light-receiving sensor.

A degree of disorder of the plurality of metasurfaces may be limited such that an average speckle size of the speckle pattern may be greater than the pixel size of the light-receiving sensor.

A degree of disorder of the plurality of metasurfaces may be limited such that an average speckle size of the speckle pattern may be greater than twice the pixel size of the light-receiving sensor.

The plurality of metasurfaces may include two to ten metasurfaces apart from each other.

A distance from the plurality of metasurfaces to the sensing surface of the light-receiving sensor may be from 1 μm to 10 cm.

According to another aspect of the disclosure, a hyperspectral imaging system includes a hyperspectral image sensor, a storage unit, and a processor. The hyperspectral image sensor includes a light-receiving sensor that is pixelated and a plurality of metasurfaces that are arranged in front of the light-receiving sensor apart from each other in a stacking direction and each have an array of meta-atoms. At least one of the plurality of metasurfaces is a random metasurface in which the meta-atoms are arranged to exhibit a disordered phase delay distribution, and a speckle pattern is formed on a sensing surface of the light-receiving sensor by the plurality of metasurfaces. The storage unit stores a random phase map information of the random metasurface. The processor is configured to generate a hyperspectral image using the speckle pattern received by the light-receiving sensor and the random phase map information.

In the random metasurface, the meta-atoms may be arranged in a disordered size distribution to exhibit the random phase map information for incident plane wave, and the random phase map may be defined as phase delay values according to coordinates in a spatial domain.

The meta-atoms of the random metasurface may have identical heights and irregular sizes.

The meta-atoms of the random metasurface may be regularly positioned.

The meta-atoms of the random metasurface may be regularly positioned and may have irregular sizes.

At least one of a number of the plurality of metasurfaces and a distance between the metasurfaces may be determined such that sizes of at least some of speckles of the speckle pattern may be greater than a pixel size of the light-receiving sensor.

A degree of disorder of the plurality of metasurfaces may be limited such that an average speckle size of the speckle pattern may be greater than the pixel size of the light-receiving sensor.

A degree of disorder of the plurality of metasurfaces may be limited such that an average speckle size of the speckle pattern may be greater than twice the pixel size of the light-receiving sensor.

The plurality of metasurfaces may include two to ten metasurfaces apart from each other.

A distance from the plurality of metasurfaces to the sensing surface of the light-receiving sensor may be from 1 μm to 10 cm.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a block diagram schematically illustrating a hyperspectral imaging system according to an embodiment;

FIG. 2 is a block diagram schematically illustrating a configuration of a hyperspectral image sensor applied to a hyperspectral imaging system, according to an embodiment;

FIG. 3 is a diagram illustrating an example in which a plurality of metasurfaces of a hyperspectral image sensor include first to third metasurfaces, according to an embodiment;

FIG. 4 is a perspective view exemplarily illustrating a stacked structure of the first to third metasurfaces of FIG. 3;

FIG. 5 is a diagram illustrating an example in which a plurality of metasurfaces of a hyperspectral image sensor include first and second metasurfaces, according to an embodiment;

FIG. 6 is a diagram illustrating an example in which a plurality of metasurfaces of a hyperspectral image sensor include first to fifth metasurfaces, according to an embodiment;

FIG. 7 is a perspective diagram illustrating an example of meta-atoms applicable to a metasurface of a hyperspectral image sensor, according to an embodiment;

FIGS. 8A to 8H are plan views illustrating various exemplary shapes of meta-atoms applicable to a metasurface of a hyperspectral image sensor, according to embodiments;

FIG. 9 is an exemplary graph illustrating a relationship between the width of meta-atoms and the phase delay of light passing through the meta-atoms;

FIG. 10 is a diagram illustrating an example of forming different random speckle patterns according to wavelengths when five random metasurfaces are stacked at intervals of about 10 μm;

FIG. 11 is a diagram schematically illustrating a method of designing a random metasurface having a limited degree of disorder to adjust the speckle size of a speckle pattern, according to an embodiment;

FIG. 12 is a diagram illustrating an exemplary process of fabricating a random metasurface from a designed random phase map;

FIG. 13 is an exemplary diagram illustrating variations in speckle size according to variations in a design parameter of a random metasurface;

FIG. 14A is a graph illustrating a variation in spectral resolution with respect to the number of stacked metasurfaces when the distance ΔL between metasurfaces is about 200 μm and an anisotropy coefficient g of a metasurface is about zero (ΔL=200 μm, g≈0);

FIG. 14B is a graph illustrating a variation in spectral resolution with respect to an anisotropy coefficient of a metasurface when five metasurfaces are stacked at intervals ΔL of about 200 μm (Nₘₑₜₐ=5, ΔL≈200 μm);

FIG. 15 is a diagram exemplarily illustrating results of comparing speckle pattern measurements and speckle pattern simulations for a single random metasurface;

FIG. 16 is a diagram exemplarily illustrating a process of photographing an object and restoring object information by using a hyperspectral image sensor according to an embodiment;

FIG. 17 is an exemplary graph illustrating variation in speckle size according to the distance between a final metasurface and a light-receiving sensor;

FIG. 18 exemplarily illustrates simulation result of spectral resolution according to a tailored numerical aperture (NA) of metasurfaces, the number N of metasurfaces, the distance D between metasurfaces, and the distance Z between a final metasurface and a light-receiving sensor;

FIG. 19 is a diagram exemplarily illustrating a process of simulating a speckle pattern when a plurality of metasurfaces are applied to a hyperspectral image sensor, according to an embodiment;

FIG. 20 is a diagram exemplarily illustrating result of a speckle pattern simulation obtained by the speckle pattern simulation method of the embodiment described with reference to FIG. 19 under the conditions of NA=0.75, N=2, D=1 mm, and Z=2 mm;

FIGS. 21A and 21B exemplarily illustrate the number N of metasurfaces and the distance D between metasurfaces as parameters for implementing a spectral resolution of about 0.1 nm when the spectral resolution is defined using the fact that speckles are differently formed according to wavelengths;

FIG. 22 exemplarily illustrates correlation curves of parameters, that is, the number N of metasurfaces and the distance D between metasurfaces, for implementing a spectral resolution of about 0.1 nm as described with reference to FIGS. 21A and 21B;

FIGS. 23A and 23B exemplarily illustrate the number N of metasurfaces and the distance D between metasurfaces as parameters for implementing a spectral resolution of about 1 nm when the spectral resolution is defined using the fact that speckles are differently formed according to wavelengths; and

FIG. 24 exemplarily illustrates correlation curves of parameters, that is, the number N of metasurfaces and the distance D between metasurfaces for implementing a spectral resolution of about 1 nm as described with reference to FIGS. 23A and 23B.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description. As used herein, the term “and/or” includes any and all combinations of one or more of the associated listed items. Expressions such as “at least one of,” when preceding a list of elements, modify the entire list of elements and do not modify the individual elements of the list.

Hereinafter, embodiments will be described with reference to the accompanying drawings. In the drawings, like reference numerals refer to like elements, and the sizes of elements may be exaggerated for clarity of illustration. The embodiments described herein are for illustrative purposes only, and various modifications may be made therein.

In the following description, when an element is referred to as being “above” or “on” another element, it may be directly on an upper, lower, left, or right side of the other element while making contact with the other element or may be above an upper, lower, left, or right side of the other element without making contact with the other element. The terms of a singular form may include plural forms unless otherwise mentioned. It will be further understood that the terms “comprises” and/or “comprising” used herein specify the presence of stated features or elements, but do not preclude the presence or addition of one or more other features or elements.

An element referred to with the definite article or a demonstrative determiner may be construed as the element or the elements even though it has a singular form.

Operations of a method may be performed in an appropriate order unless explicitly described in terms of order or described to the contrary, and are not limited to the stated order thereof.

In the disclosure, terms such as “unit” or “module” may be used to denote a unit that has at least one function or operation and is implemented with hardware, software, or a combination of hardware and software.

Furthermore, line connections or connection members between elements depicted in the drawings represent functional connections and/or physical or circuit connections by way of example, and in actual applications, they may be replaced or embodied with various additional functional connections, physical connections, or circuit connections.

Examples or exemplary terms are just used herein to describe technical ideas and should not be considered for purposes of limitation unless defined by the claims.

According to embodiments, a hyperspectral image sensor may be provided such that a speckle pattern may be formed on a sensing surface of a light-receiving sensor by a plurality of metasurfaces arranged apart from each other in a stacking direction, and at least one of the metasurfaces may be a random metasurface. In this case, at least one of the number of metasurfaces and the distance between metasurfaces may be determined such that the size of at least some speckles of the speckle pattern formed on the sensing surface of the light-receiving sensor is greater than the pixel size of the light-receiving sensor. In addition, the degree of disorder of the metasurfaces may be limited such that the average speckle size of the speckle pattern may be greater than the pixel size of the light-receiving sensor. Here, as is well known, the speckle pattern refers to a pattern in which bright regions (speckle grains) are distributed in random positions, brightness, and sizes on a dark background. The term “speckle size” may refer to the average size of bright regions (speckle grains) of a speckle pattern. For example, a speckle size may be calculated by taking the autocorrelation of a speckle pattern image and calculating the full width half maximum (FWHM) of a peak. The average speckle size of a speckle pattern may be the average size of bright regions of an overall speckle pattern.

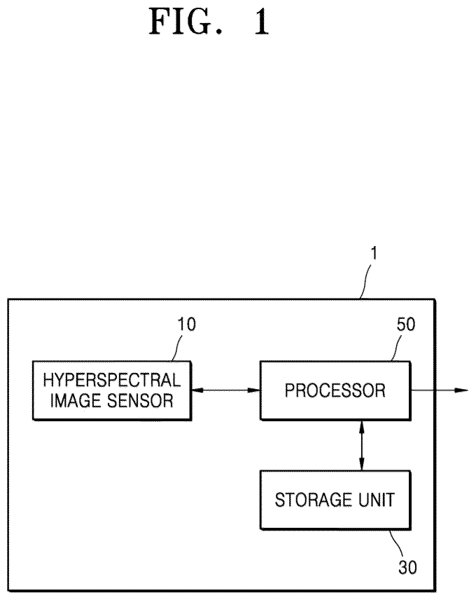

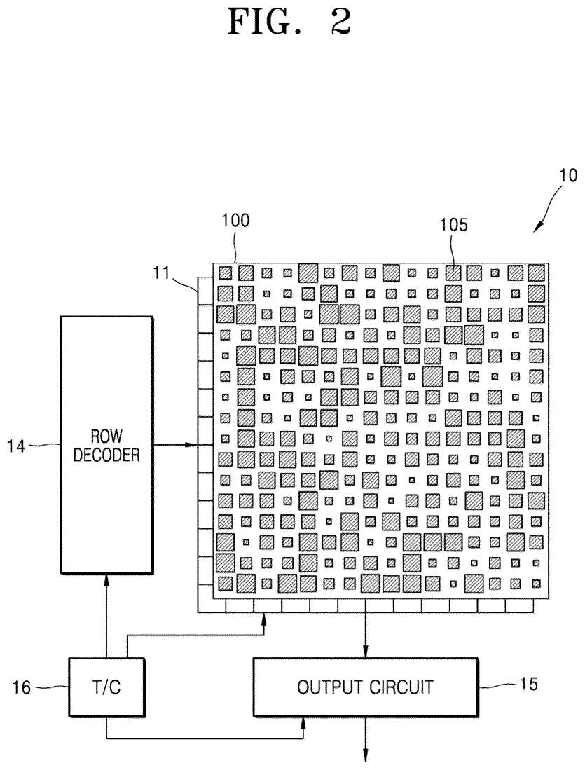

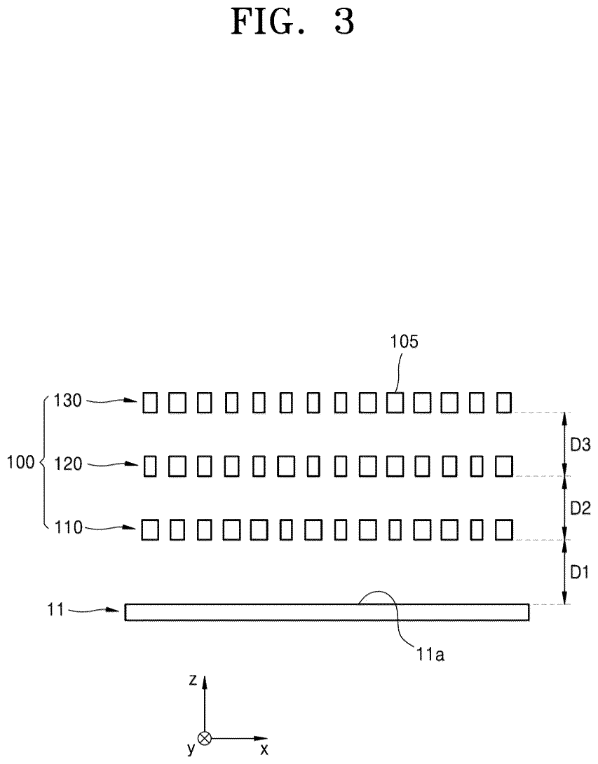

FIG. 1 is a block diagram schematically illustrating a hyperspectral imaging system 1 according to an embodiment. FIG. 2 is a block diagram schematically illustrating a configuration of a hyperspectral image sensor 10 applied to the hyperspectral imaging system 1 according to an embodiment. FIG. 3 is a diagram illustrating an exemplary arrangement of a plurality of metasurfaces 100 and a light-receiving sensor 11 in the hyperspectral image sensor 10 according to an embodiment.

Referring to FIG. 1, the hyperspectral imaging system 1 of the embodiment includes the hyperspectral image sensor 10, a storage unit 30 configured to store information, and a processor 50 configured to generate a hyperspectral image by processing a signal from the hyperspectral image sensor 10.

Referring to FIGS. 2 and 3, the hyperspectral image sensor 10 includes a light-receiving sensor 11 that is pixelated, and a plurality of metasurfaces 100 that are arranged in front of the light-receiving sensor 11 to form a speckle pattern on a sensing surface 11a of the light-receiving sensor 11. The plurality of metasurfaces 100 may include two or more metasurfaces, and at least one of the plurality of metasurfaces 100 may be a random metasurface. The hyperspectral image sensor 10 may further include a timing controller 16, a row decoder 14, and an output circuit 15.

The light-receiving sensor 11 that is pixelated may include a pixel array in which a plurality of pixels are two-dimensionally arranged on the sensing surface 11a. A speckle pattern may be formed on the sensing surface 11a of the light-receiving sensor 11 by the plurality of metasurfaces 100, and the pixels of the light-receiving sensor 11 may have a size less than at least some of speckle sizes of the speckle pattern. The pixels may be micro-sized or sub-micro-sized.

The row decoder 14 may select one or two or more of rows of the pixel array of the light-receiving sensor 11 in response to a row address signal that is output from the timing controller 16. The output circuit 15 may output light-sensing signals in units of columns from a plurality of pixels arranged in the selected row. To this end, the output circuit 15 may include a column decoder, an analog-to-digital converter (ADC), and the like. For example, the output circuit 15 may include a plurality of ADCs respectively arranged for columns between the column decoder and the light-receiving sensor 11, or may include one ADC disposed at an output terminal of the column decoder. The timing controller 16, the row decoder 14, and the output circuit 15 may be implemented as a single chip or as separate chips. The processor 50 configured to process image signals output through the output circuit 15 may be implemented as a single chip together with the timing controller 16, the row decoder 14, and the output circuit 15.

Referring back to FIG. 1, the storage unit 30 may store phase map information with respect to a random metasurface of the plurality of metasurfaces 100, that is, random phase map information. The random phase map information of the random metasurface may be defined by phase delay values according to coordinates, and the phase delay values may be stored in the storage unit 30. Here, when the plurality of metasurfaces 100 include at least one regular metasurface in which meta-atoms are regularly distributed, phase map information about the regular metasurface may also be stored in the storage unit 30. In this manner, the storage unit 30 may store phase map information about the plurality of metasurfaces 100.

The processor 50 may generate a hyperspectral image by using speckle pattern information received by the light-receiving sensor 11 of the hyperspectral image sensor 10 and phase map information stored in the storage unit 30.

In the hyperspectral image sensor 10 according to the embodiment, as exemplarily shown in FIG. 3, the plurality of metasurfaces 100 may be apart from each other in a stacking direction (z-axis direction or-z-axis direction), and each metasurface 100 may have an array of meta-atoms 105. At least one of the plurality of metasurfaces 100 may be a random metasurface in which meta-atoms 105 are arranged to exhibit a disordered phase delay distribution, and a speckle pattern may be formed on the sensing surface 11a of the light-receiving sensor 11 by the plurality of metasurfaces 100. For example, the random metasurface may have meta-atoms 105 arranged in a disordered size distribution to indicate random phase map information with respect to incident plane wave.

Here, the stacking direction may refer to a direction in which the plurality of metasurfaces 100 and the light-receiving sensors 11 are disposed, and a speckle pattern may be formed on the sensing surface 11a of the light-receiving sensor 11 by the plurality of metasurfaces 100 disposed apart from each other in the stacking direction.

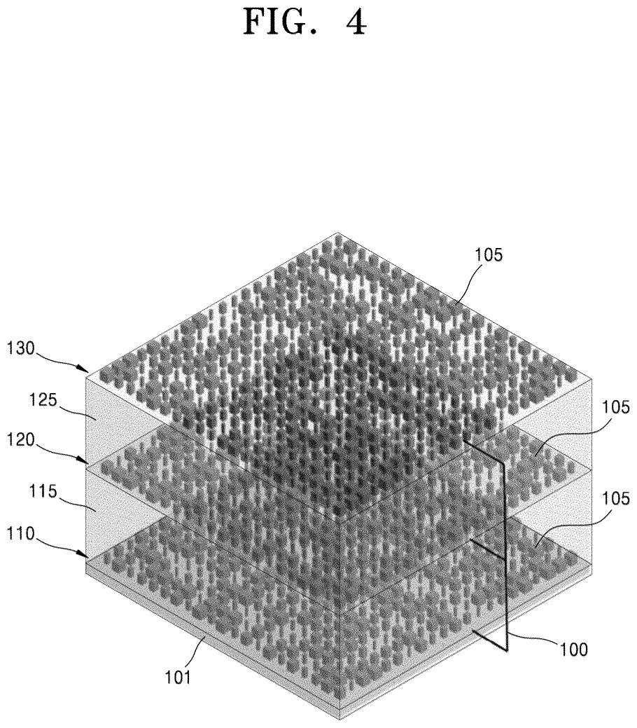

FIG. 3 is a diagram exemplarily illustrating an arrangement relationship between the plurality of metasurfaces 100 and the light-receiving sensor 11 when the plurality of metasurfaces 100 include first to third metasurfaces 110, 120, and 130. FIG. 4 is a perspective view exemplarily illustrating a stacked structure of the first to third metasurfaces 110, 120, and 130 of FIG. 3.

Referring to FIGS. 3 and 4, the hyperspectral image sensor 10 may include the first to third metasurfaces 110, 120, and 130 that are arranged at a front end of the light-receiving sensor 11, which are spaced apart from each other in the stacking direction. When viewed from a side through which light is incident, the third metasurface 130 corresponds to a starting metasurface, and the first metasurface 110 corresponds to a final metasurface positioned at a front end of the light-receiving sensor 11.

Each of the first to third metasurfaces 110, 120, and 130 may have an array of meta-atoms 105. The first metasurface 110 may be at a distance D1 from the sensing surface 11a of the light-receiving sensor 11. The second metasurface 120 may be at a distance D2 from the first metasurface 110. The third metasurface 130 may be at a distance D3 from the second metasurface 120. Here, the distances D2 and D3 may be equal to each other or may be different from each other. That is, the first to third metasurfaces 110, 120, and 130 may be arranged apart from each other at regular intervals, or at least some of the first to third metasurfaces 110, 120, and 130 may be arranged apart from each other at different intervals. In FIGS. 3 and 4 and the following drawings, the height and width of each meta-atom 105 are exaggerated for clarity of illustration. As described later in design examples, the height of meta-atoms 105 and the distances D2 and D3 between the first to third metasurfaces 110, 120, and 130 are several tens to several hundreds of times or more different, and thus when the distances D2 and D3 between the first to third metasurfaces 110, 120, and 130 are expressed, the height of meta-atoms 105 may or may not be considered.

At least some of the first to third metasurfaces 110, 120, and 130 may be, for example, a random metasurface. That is, each of the first to third metasurfaces 110, 120, and 130 may be a random metasurface, or one or two or more of the first, second, and third photosensitive cells 110, 120, and 130 may be a random metasurface. FIG. 4 shows an example in which the first to third metasurfaces 110, 120, and 130 are random metasurfaces. That is, the first to third metasurfaces 110, 120, and 130 may be first to third random metasurfaces. Hereinafter, a case in which each of the plurality of metasurfaces 100 is a random metasurface and random phase map information about each random metasurface is stored in the storage unit 30 will be described as an example. However, embodiments are not limited thereto.

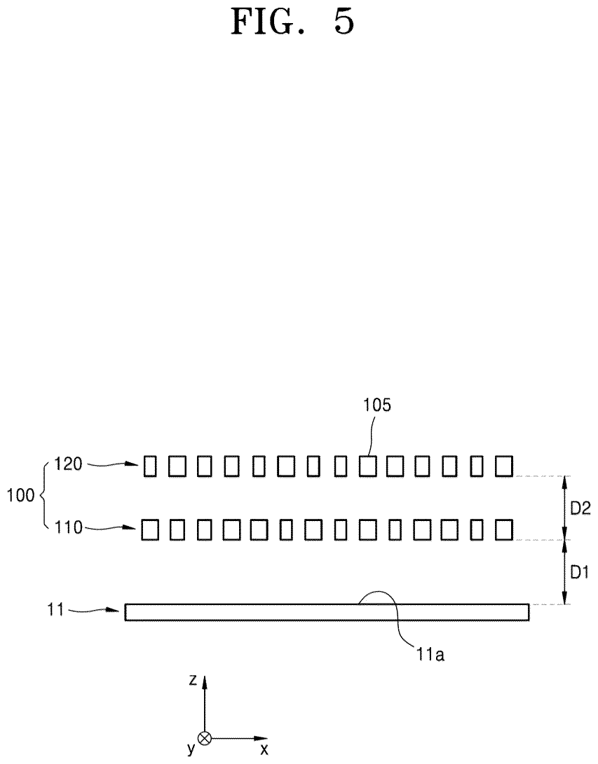

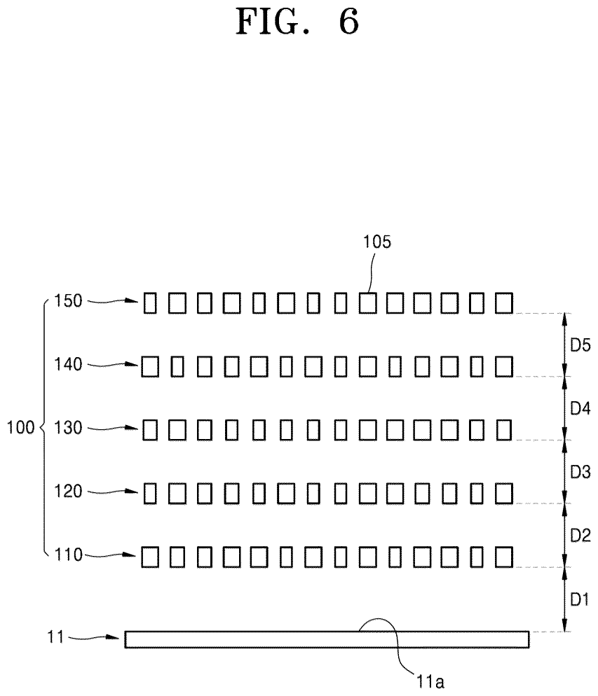

FIGS. 3 and 4 show an example in which the plurality of metasurfaces 100 include the first to third metasurfaces 110, 120, and 130. However, the number of metasurfaces 100 may vary as in examples shown in FIGS. 5 and 6.

For example, as shown in FIG. 5, the plurality of metasurfaces 100 may include first and second metasurfaces 110 and 120. That is, the hyperspectral image sensor 10 may include the first and second metasurfaces 110 and 120 arranged apart from each other in the stacking direction at front of the light-receiving sensor 11. Each of the first and second metasurfaces 110 and 120 may have an array of meta-atoms 105. The first metasurface 110 may be at a distance D1 from the sensing surface 11a of the light-receiving sensor 11. The second metasurface 120 may be at a distance D2 from the first metasurface 110. Each of the first and second metasurfaces 110 and 120 may be, for example, a random metasurface. Alternatively, only one of the first metasurface 110 and the second metasurface 120 may be a random metasurface.

In addition, as shown in FIG. 6, the plurality of metasurfaces 100 may include first to fifth metasurfaces 110, 120, 130, 140, and 150. That is, the hyperspectral image sensor 10 may include the first to fifth metasurfaces 110, 120, 130, 140, and 150 arranged apart from each other in the stacking direction at front of the light-receiving sensor 11. Each of the first to fifth metasurfaces 110, 120, 130, 140, and 150 may have an array of meta-atoms 105. The first metasurface 110 may be at a distance D1 from the sensing surface 11a of the light-receiving sensor 11. The second metasurface 120 may be at a distance D2 from the first metasurface 110. The third metasurface 130 may be at a distance D3 from the second metasurface 120. The fourth metasurface 140 may be at a distance D4 from the third metasurface 130. The fifth metasurface 150 may be at a distance D5 from the fourth metasurface 140. Here, the distances D2, D3, D4, and D5 may be equal to each other, or at least some of the distances D2, D3, D4, and D5 may be different from each other. That is, the first to fifth metasurfaces 110, 120, 130, 140, and 150 may be arranged apart from each other at regular intervals, or at least some of the first to fifth metasurfaces 110, 120, 130, 140, and 150 may be arranged apart from each other at different intervals.

Each of the first to fifth metasurfaces 110, 120, 130, 140, and 150 may be, for example, a random metasurface. Alternatively, four or less of the first to fifth metasurfaces 110, 120, 130, 140, and 150 may be random metasurfaces. Here, an example in which the first to fifth metasurfaces 110, 120, 130, 140, and 150 are all random metasurfaces is considered.

Furthermore, in FIGS. 3, 5, and 6, the distances D1, D2, D3, D4, and D5 sequentially indicate only each separation distance from adjacent metasurface based on the light-receiving sensor 11, and distances denoted with the same designation in FIGS. 3, 5, and 6 are not limited to having the same values. For example, the distances D1, D2, and D3 may have the same values in the embodiments shown in FIGS. 3, 5, and 6, the same values or different values in some of the embodiments shown in FIGS. 3, 5, and 6, or different values in the embodiments shown in FIGS. 3, 5, and 6.

As exemplarily illustrated in FIGS. 3 to 6, the plurality of metasurfaces 100 may include two or more metasurfaces arranged apart from each other in the stacking direction. For example, the plurality of metasurfaces 100 may include two to ten metasurfaces arranged apart from each other. For example, the plurality of metasurfaces 100 may include two to five metasurfaces arranged apart from each other. At least some of the plurality of metasurfaces 100 may be random metasurfaces. Here, an example in which each of the plurality of metasurfaces 100 is a random metasurface is described. However, embodiments are not limited thereto.

Each of the plurality of metasurfaces 100 may be a random metasurface, and meta-atoms 105 may be arranged in a disordered size distribution to exhibit random phase map information with respect to incident plane wave. In this case, a random phase map may be defined by phase delay values according to coordinates in a spatial domain.

Meta-atoms 105 may be formed at the same height and/or may be regularly positioned on each of the plurality of metasurfaces 100, and the sizes of the meta-atoms 105 may be irregular. As a result, a disordered array of meta-atoms 105 exhibiting a disordered phase delay distribution may be formed.

For example, as exemplarily illustrated in FIG. 4, meta-atoms 105 may be formed at the same height and may be regularly positioned on each of the first to third metasurfaces 110, 120, and 130, and only the size distribution of meta-atoms 105 may be irregular. As a result, a disordered array of meta-atoms 105 exhibiting a disordered phase delay distribution may be formed. Variations in the size of meta-atoms 105 may be obtained by, for example, variations in the horizontal width and/or longitudinal width of meta-atoms 105. For example, the meta-atoms 105 may have a quadrangular pillar shape or a pillar shape having various cross-sectional shapes.

In addition, as exemplarily illustrated in FIGS. 2 to 6, the meta-atoms 105 of the plurality of metasurfaces 100 may be periodically positioned. In this case, the meta-atoms 105 may be arranged with the same period for all of the plurality of metasurfaces 100, with different periods for some of the plurality of metasurfaces 100, or with different periods for each of the plurality of metasurfaces 100. In addition, the meta-atoms 105 may have the same height on all of the plurality of metasurfaces 100, different heights on some of the plurality of metasurfaces 100, or different heights respectively on the plurality of metasurfaces 100. In addition, the meta-atoms 105 may have different heights even on one metasurface.

In this manner, the meta-atoms 105 of the plurality of metasurfaces 100 may be periodically positioned and may have irregular sizes corresponding to a random phase map to be implemented, thereby forming a disordered arrangement. For example, the meta-atoms 105 may form a disordered arrangement exhibiting a disordered phase delay distribution when the meta-atoms 105 are periodically arranged and have the same height and different widths (or diameters). When the meta-atoms 105 have different widths, an effective refractive index may vary according to the widths of the meta-atoms 105, and thus, the degree of phase delay may be different. The meta-atoms 105 may have different widths within the range of about 60 nm to about 300 nm, but are not limited thereto. Phase may be modulated by the disordered arrangement of the meta-atoms 105, and thus, a speckle pattern may be formed by resultant interference.

In addition, referring to FIG. 4, a metasurface that is closest to the light-receiving sensor 11 or farthest from the light-receiving sensor 11, for example, the first metasurface 110 or the third metasurface 130 when the plurality of metasurfaces 100 include three metasurfaces, may be formed on a substrate 101, and adjacent metasurfaces may be spaced apart by spacer layers 115 and 125 each other. In the example shown in FIG. 4, the first metasurface 110 is formed on the substrate 101, the spacer layer 115 is formed between the first metasurface 110 and the second metasurface 120, and the spacer layer 125 is formed between the second metasurface 120 and the third metasurface 130. The first metasurface 110 may be configured as a structure in which meta-atoms 105 are disorderly arranged on the substrate 101. The spacer layer 115 may be formed on the first metasurface 110, and the second metasurface 120 may be formed on the spacer layer 115. The spacer layer 125 may be formed on the second metasurface 120, and the third metasurface 130 may be formed on the spacer layer 125. As described above, the second metasurface 120 and the third metasurface 130 may have a configuration in which meta-atoms 105 are disorderly arranged on the spacer layers 115 and 125.

When the spacer layer 115 is formed, spaces between the meta-atoms 105 of the first metasurface 110 may be filled with a material of the spacer layer 115. In addition, when the spacer layer 125 is formed, spaces between the meta-atoms 105 of the second metasurface 120 may be filled with a material of the spacer layer 125. Spaces between the meta-atoms 105 of the outmost metasurface, that is, the third metasurface 130, may or may not be filled with a spacer layer material. In another example, spaces between the meta-atoms 105 may be filled with another material different from the materials of the spacer layers 115 and 125 or may remain empty. FIG. 4 shows an example in which the spaces between the meta-atoms 105 of the first and second metasurfaces 110 are filled with the materials of the spacer layers 115 and 125, and the spaces between the meta-atoms 105 of the third metasurface 130 remain empty. However, embodiments are not limited thereto, and various modifications may be made as described above. Here, the materials of the spacer layers 115 and 125 or the other material filling the spaces between the meta-atoms 105 may have a refractive index that is different from the refractive index of the meta-atoms 105.

The substrate 101 and the spacer layers 115 and 125 may include a transparent material. At least one of the substrate 101 and the spacer layers 115 and 125 may include, for example, an amorphous silicon oxide such as fused silica, but is not limited thereto and may include various transparent materials. Here, metasurfaces may be also formed on each substrate and may be coupled to each other in a state in which the metasurfaces are spaced apart from each other.

Here, the spatial arrangement structure, materials, or the like of the first to third metasurfaces 110, 120, and 130 described with reference to FIG. 4 may be also applied to other cases in which the plurality of metasurfaces 100 include different numbers of metasurfaces as shown in FIGS. 5 and 6.

As described above, the hyperspectral image sensor 10 according to an embodiment may include the plurality of metasurfaces 100 apart from each other, and at least some of the plurality of metasurfaces 100 may include random metasurfaces. Each of the plurality of metasurfaces 100 may include a random metasurface. Furthermore, in the hyperspectral image sensor 10 according to an embodiment, the number of metasurfaces, the separation distance between the metasurfaces, and the separation distance between a final metasurface (for example, the first metasurface 110) and the sensing surface 11a of the light-receiving sensor 11 may be determined to form a random speckle pattern capable of resolving wavelengths and spaces with a sufficient resolution. For example, the number of metasurfaces, the separation distance between the metasurfaces, the separation distance between a final metasurface and the sensing surface 11a of the light-receiving sensor 11, the degree of disorder of the metasurfaces, and the like may be determined to form a distinguishable random speckle pattern for each wavelength in units of nanometers (nm) or sub-nanometers (sub-nm), for example, in units of about 0.1 nm and thus to obtain high-resolution hyperspectral images in a wavelength range of interest such as a wavelength range of about 400 nm to about 700 nm.

To this end, the plurality of metasurfaces 100 may be provided to form a speckle pattern overall on the sensing surface 11a of the light-receiving sensor 11, and at least one of the number of metasurfaces, the separation distance between metasurfaces, and the separation distance between the final metasurface (for example, the first metasurface 110) and the sensing surface 11a of the light-receiving sensor 11 may be determined such that speckle sizes of at least some speckles of the speckle pattern formed on the sensing surface 11a of the light-receiving sensor 11 may be greater than the pixel size of the light-receiving sensor 11. In addition, the degree of disorder of the plurality of metasurfaces 100 may be limited such that the average speckle size of the speckle pattern may be greater than the pixel size of the light-receiving sensor 11. For example, the degree of disorder of the plurality of metasurfaces 100 may be limited such that the average speckle size of the speckle pattern may be greater than twice the pixel size of the light-receiving sensor 11.

For example, according to embodiments, as described above, the plurality of metasurfaces 100 of the hyperspectral image sensor 10 may include two to ten metasurfaces apart from each other. In addition, for example, the metasurfaces may be spaced apart at intervals of micrometers (μm) to millimeters (mm). In addition, the separation distance between the sensing surface 11a of the light-receiving sensor 11 and the first metasurface 110 adjacent to the light-receiving sensor 11 may be greater than the separation distance between metasurfaces. The distance between the sensing surface 11a of the light-receiving sensor 11 and the first metasurface 110 adjacent to the light-receiving sensor 11 may be within the range of about 1 μm to about 10 cm, for example, 100 μm.

According to embodiments, in the hyperspectral image sensor 10 and the hyperspectral imaging system 1 including the hyperspectral image sensor 10, a speckle pattern of which the size of at least some speckles is greater than the pixel size of the light-receiving sensor 11 is formed by the plurality of metasurfaces 100, and an image of the speckle pattern is received and converted into a signal by the light-receiving sensor 11 in units of pixels. Thus, not only when the light-receiving sensor 11 has a pixel size in μm, but also when the light-receiving sensor 11 has a pixel size of 1 μm or less, the light receiving efficiency of the light-receiving sensor 11 may be increased, and a hyperspectral image may be generated using the signal acquired from the light-receiving sensor 11 and the random phase map information stored in the storage unit 30.

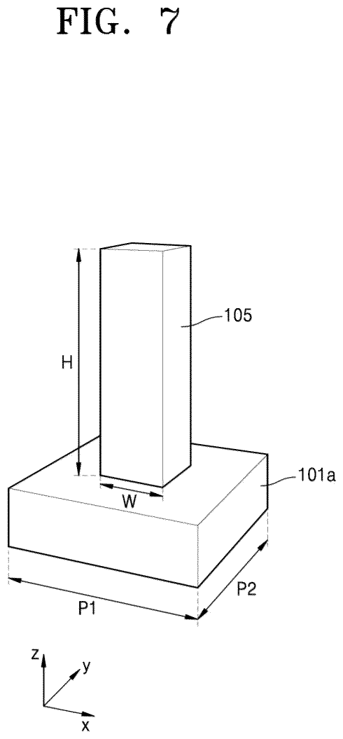

FIG. 7 is a perspective view illustrating an example of a meta-atom 105 applicable to the plurality of metasurfaces 100 of the hyperspectral image sensor 10 according to an embodiment.

Referring to FIG. 7, the meta-atom 105 may be formed in a square pillar shape on a base layer 101a. The base layer 101a may correspond to any one of the substrate and the spacer layer described above. For example, the base layer 101a may include an amorphous silicon oxide such as fused silica. Alternatively, the base layer 101a may include another transparent material.

At least one of the width W and the height H of the meta-atom 105 may be sub-wavelength. In addition, the meta-atom 105 shown in FIG. 7 may be arranged with periods P1 and P2 that may or may not be sub-wavelength. Referring to FIG. 7, P1 refers to the arrangement period of meta-atoms 105 in a horizontal direction (x-axis direction), and P2 refers to the arrangement period of meta-atoms 105 in a longitudinal direction (y-axis direction). The arrangement periods P1 and P2 of meta-atoms 105 may be constant in the horizontal direction and the longitudinal direction. That is, P1 may be equal to P2 (P1=P2). In another example, the arrangement period P1 of meta-atoms 105 in the horizontal direction may be different from the arrangement period P2 of the meta-atoms 105 in the longitudinal direction.

The width W of the meta-atoms 105 may vary depending on the position of the meta-atoms 105. The meta-atoms 105 may include a material of which the effective refractive index varies according to the width W of the meta-atoms 105. The meta-atoms 105 may include, for example, a silicon nitride such as Si₃N₄. In addition, the material of the meta-atoms 105 may selected from various materials as long as the effective refractive index of the meta-atoms 105 varies according to the width W of the meta-atoms 105.

In the hyperspectral image sensor 10 according to an embodiment, meta-atoms 105 of the metasurfaces 100 may be, for example, made of silicon nitride, and may be formed on the base layer 101a including an amorphous silicon oxide with a period (P1=P2) of about 350 nm in the horizontal direction and the longitudinal direction, and with a height H of about 900 nm to form a disordered size arrangement by varying the width W of the meta-atoms 105. Here, the periods P1 and P2, the height H, and the material of the meta-atoms 105 are merely an example, and embodiments are not limited thereto. The periods P1 and P2, the height H, and the material of the meta-atoms 105 may vary according to design conditions.

In the hyperspectral image sensor 10 according to an embodiment, the meta-atoms 105 of the metasurfaces 100 may have a square pillar shape or other pillar shapes having various cross-sectional shapes such as a circular cross-sectional shape, an elliptical cross-sectional shape, a rectangular cross-sectional shape, a square-ring cross-sectional shape, a circular-ring cross-sectional shape, or a cross-shaped cross-sectional shape.

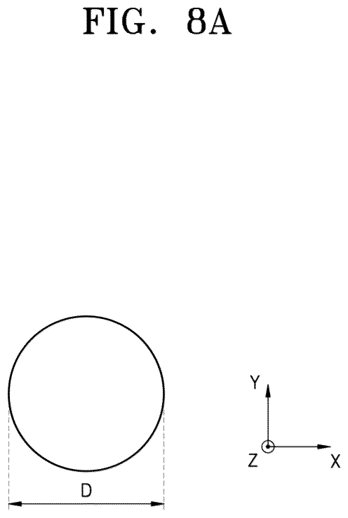

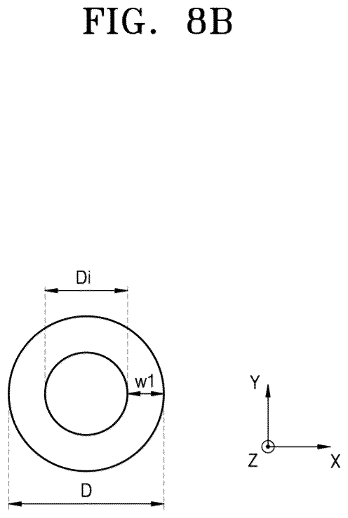

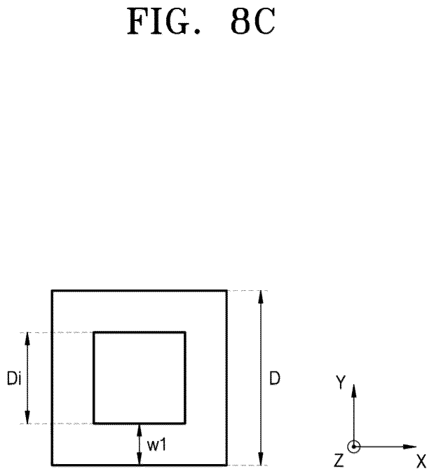

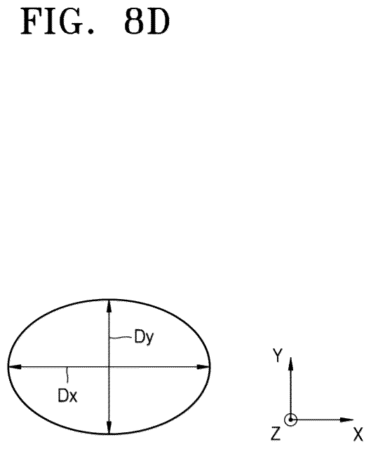

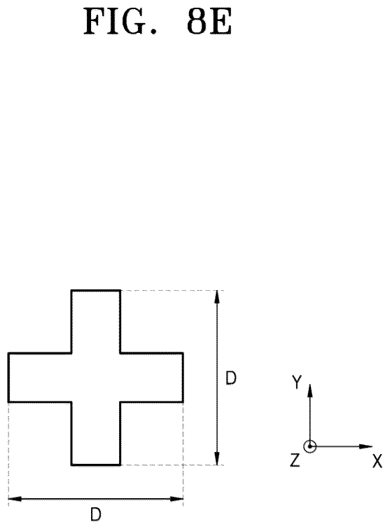

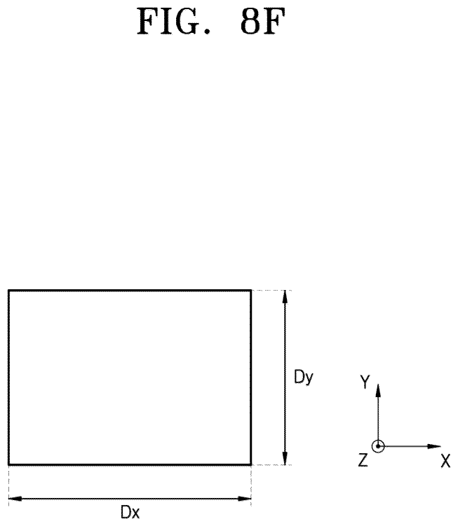

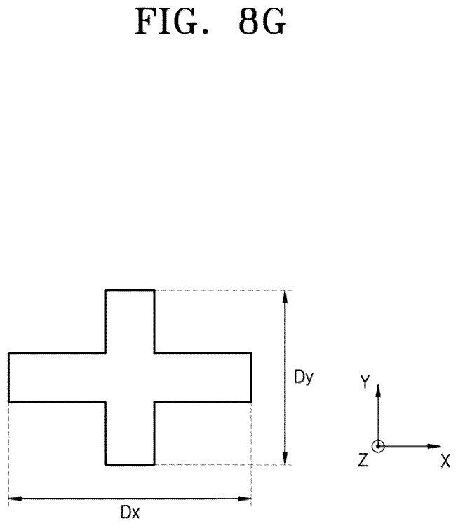

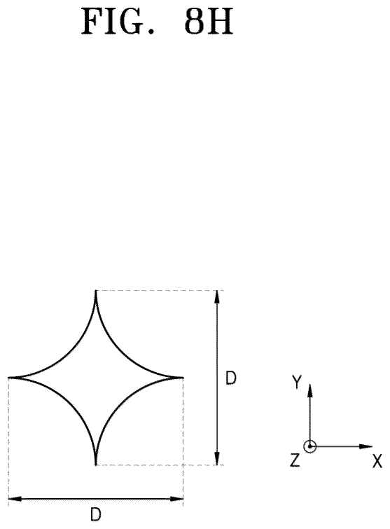

FIGS. 8A to 8H are plan views illustrating various exemplary shapes of meta-atoms 105 that may be applied to the metasurfaces 100 of the hyperspectral image sensor 10.

As shown in FIG. 8A, the cross-sectional shape of the meta-atoms 105 may be circular with a diameter D. The diameter D of the meta-atoms 105 having a circular pillar shape may be sub-wavelength. As shown in FIGS. 8B and 8C, the cross-sectional shape of the meta-atoms 105 may be a circular ring shape or a square ring shape each having an outer diameter D and an inner diameter Di. The width W1 of each ring shape may be sub-wavelength. As shown in FIG. 8D, the cross-sectional shape of the meta-atoms 105 may be an elliptical shape having a major axis Dx in a first direction (for example, X-axis direction) that is different from a minor axis Dy in a second direction (for example, Y-axis direction). As shown in FIG. 8E, the meta-atoms 105 may have a cross-shaped cross-sectional shape. As shown in FIGS. 8F and 8G, the cross-sectional shape of the meta-atoms 105 may be a rectangular shape or a cross shape each having a length Dx in the first direction (for example, X-axis direction) that is different from a length Dy in the second direction (for example, Y-axis direction). In addition, as shown in FIG. 8H, the cross-sectional shape of the meta-atoms 105 may have a plurality of concave arcs.

As described above, according to embodiments, the meta-atoms 105 applicable to the metasurfaces 100 of the hyperspectral image sensor 10 may have pillar shapes having various cross-sectional shapes as well as a square pillar shape.

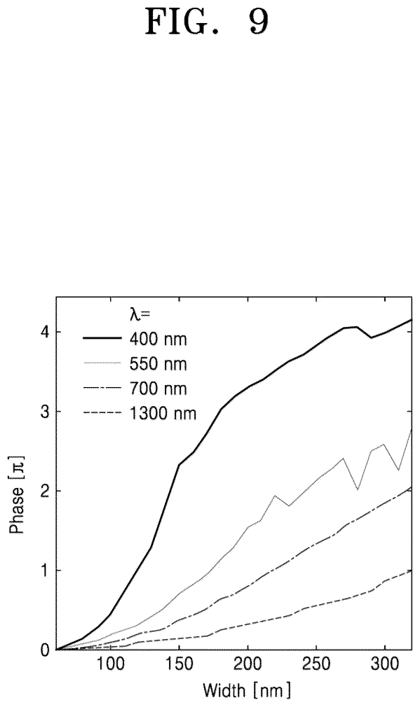

FIG. 9 is an exemplary graph illustrating a relationship between the width of meta-atoms 105 and the phase delay of light passing through the meta-atoms 105. FIG. 9 shows a relationship between a width of the meta-atoms 105 and a phase delay occurring by the meta-atoms 105 when the meta-atoms 105 are made of Si₃N₄, have a rectangular pillar shape and a height of about 900 nm, and are arranged with a period of about 350 nm.

As shown in FIG. 9, the degree of phase delay varies according to the width of the meta-atoms 105 and the wavelength of light. Thus, the relationship between the width of the meta-atoms 105 and the phase delay occurring by the meta-atoms 105 may be recorded as lookup table data, and the lookup table data may be stored in the storage unit 30. In addition, based on this relationship, the metasurfaces 100 may be formed by substituting a two-dimensional random phase map with a width map (process design diagram) of two-dimensional meta-atoms 105.

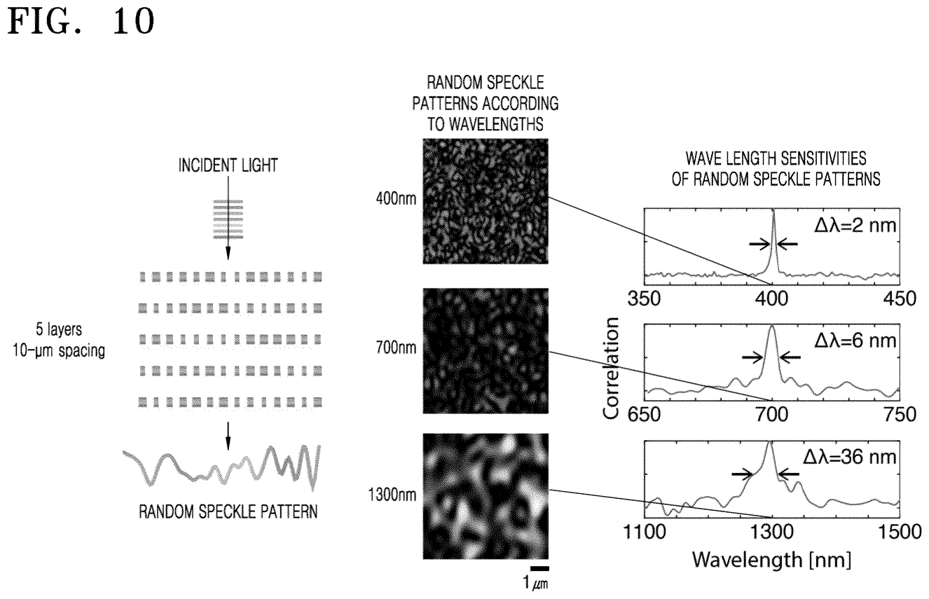

FIG. 10 shows an example of forming different random speckle patterns according to wavelengths when five random metasurfaces are stacked at intervals of about 10 μm. In FIG. 10, center images and corresponding right graphs show random speckle patterns and wavelength sensitivities of random speckle patterns respectively obtained at wavelengths of about 400 nm, about 700 nm, and about 1300 nm. In each of graphs showing wavelength sensitivities, a horizontal axis refers to wavelength (unit: nm), and a vertical axis refers to correlation.

As shown in FIG. 10, when a stack-type propagation medium is formed by five random metasurfaces stacked at intervals of about 10 μm, different random speckle patterns may be formed depending on wavelengths, and the stack-type propagation medium may have a transmittance of about 90% or more and a spectral resolution of about 1 nm to 30 nm. In addition, the random speckle pattern produced by incident light having a wavelength of about 400 nm may have a spectral resolution of about 2 nm, and a correlation with the random speckle pattern produced by incident light having a wavelength of about 400±2 nm, which is about 0.5 or less.

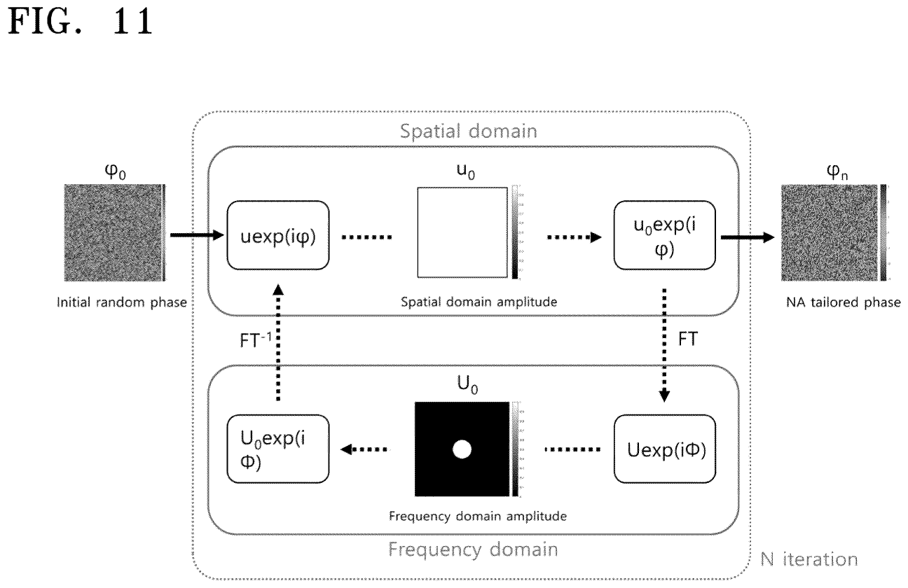

FIG. 11 is a diagram schematically illustrating a method of designing a random metasurface having a limited degree of disorder to adjust the speckle size of a speckle pattern.

Referring to FIG. 11, a phase shift that incident plane wave undergoes due to a random metasurface may be defined by a random phase map of the random metasurface, and such random phase map is a function defined by phase delay values according to coordinates in a spatial domain.

For an initial random phase (φ₀) map, an optimization algorithm may be performed on by repeatedly applying intensity constraints while alternating between a spatial domain and a Fourier domain (frequency domain). The optimization algorithm may be repeated

N times (N iterations) while alternating between the spatial domain and the Fourier domain (frequency domain). For example, the Gerchberg-Saxton algorithm may be used as the iterative optimization algorithm.

The Fourier transform (FT) may be performed from the spatial domain to the Fourier domain, and the inverse Fourier transform (FT⁻¹) may be performed from the Fourier domain to the spatial domain. In addition, for example, a spatial domain amplitude u₀ may not be limited, a Fourier domain amplitude U₀ (frequency domain amplitude U₀) may be limited, and thus a Fourier domain component of the random phase map may be limited. The limited Fourier domain component may be expressed by a numerical aperture NA. By limiting the Fourier domain component NA of the random phase map, the speckle size may be adjusted. That is, a random phase map with a tailored phase φₙ of a numerical aperture NA− may be obtained to implemnet a metasurface having a limited degree of disorder as intended.

As described above, a two-dimensional random phase map corresponding to a metasurface having a limited degree of disorder may be obtained by performing an iterative optimization algorithm that imposes intensity constraints, and each metasurface may be produced by substituting the two-dimensional random phase map with a width map (process design diagram) of two-dimensional meta-atoms 105. An optimization algorithm for designing each metasurface may be performed such that the average speckle size of a speckle pattern may be greater than the pixel size of the light-receiving sensor 11, for example, greater than twice the pixel size of the light-receiving sensor 11 due to a stacked structure of the plurality of metasurfaces 100 each manufactured in this way.

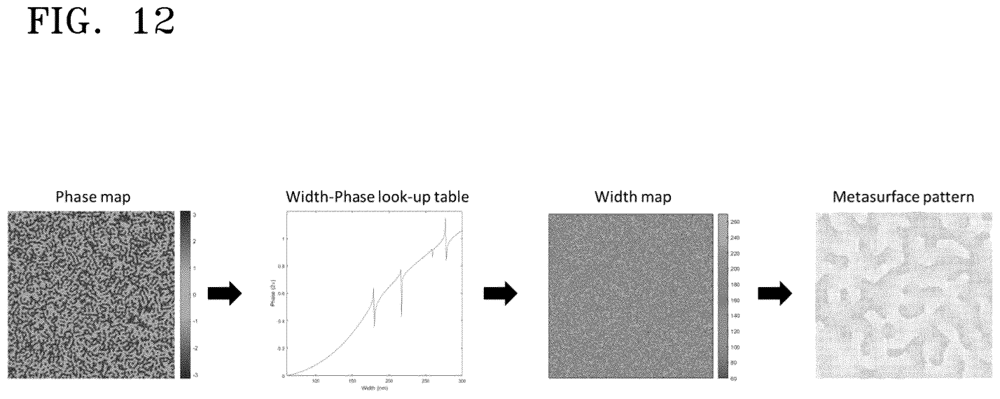

FIG. 12 shows an exemplary process of fabricating a random metasurface from a designed random phase map.

As shown in FIG. 12, a designed random phase map may be converted into a width map of meta-atoms 105 based on a lookup table indicating a relationship between the width of meta-atoms 105 and a phase delay occurring by the meta-atoms 105, and a metasurface pattern in which meta-atoms 105 are arranged with a limited degree of disorder may be fabricated using the width map.

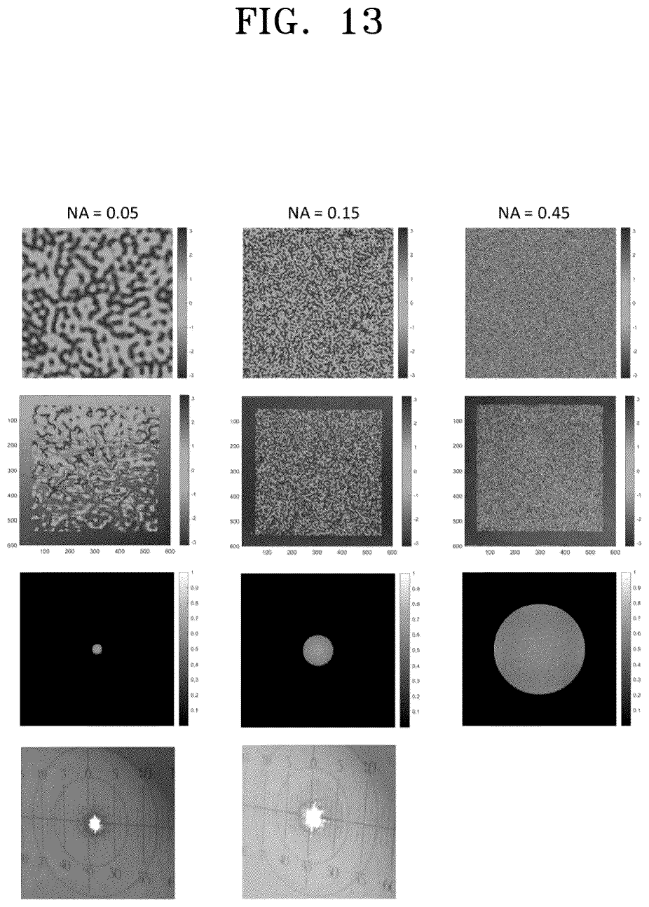

FIG. 13 shows speckle size variations according to random metasurface design parameters. In FIG. 13, when a limited Fourier domain component NA has values of 0.05, 0.15, and 0.45, simulated phase maps, phase maps measured with respect to fabricated random metasurfaces, simulated Fourier domains (frequency domains), and far-field images corresponding thereto are shown.

As shown in FIG. 13, the speckle size may vary when the limited Fourier domain component NA varies to 0.05, 0.15, and 0.45. In addition, the simulated phase maps and the phase maps measured with respect to the fabricated random metasurfaces exhibit similar speckle size characteristics for each of the limited Fourier domain components NA, and based on this, it could be understood that a random metasurface having a constrained degree of disorder may be implemented by the limited Fourier domain component NA.

In addition, according to the theory of coherence relation, a spectral resolution Δλ by a scattering medium may be proportional to a free scattering distance in the scattering medium and may be inversely proportional to the square of the thickness of the scattering medium.

As in the hyperspectral image sensor 10 according to an embodiment and the hyperspectral imaging system 1 including the hyperspectral image sensor 10, when a scattering medium is formed by a stacked structure of a plurality of metasurfaces, a free scattering distance in the scattering medium corresponds to an inter-metasurface distance ΔL, and the thickness of the scattering medium is approximately equal to the product of the inter-metasurface distance ΔL and a number less than the number of metasurfaces by 1 (number of metasurfaces−1). Thus, the spectral resolution Δλ may be approximately inversely proportional to the inter-metasurface distance ΔL and the square of the number of metasurfaces 100. Here, for example, the inter-metasurface distance ΔL may correspond to the distances D2, D3, D4, and D5 in FIGS. 3, 5, and 6.

For example, when the scattering medium is formed by a stacked structure of the plurality of metasurfaces 100 spaced apart from each other, the conditions of Δλ=Δf×λ_{c}²/c and Δf≈2c/(N²×Iₜ) may be satisfied. Here, λ_{c} refers to a center wavelength, and N refers to the number of metasurfaces. Iₜ refers to a transport mean free path and may correspond to an inter-metasurface distance. That is, spectral resolution may be improved as the inter-metasurface distance increases and the number of metasurfaces increases, and the inter-metasurface distance and/or the number of metasurfaces may have critical values. In an ideal case, two metasurfaces arranged at a distance of about 200 μm from each other may guarantee a spectral resolution of about 0.1 nm.

Therefore, a spectral resolution by the stacked structure of the plurality of metasurfaces 100 may be controlled using the number of stacked metasurfaces and the distance between the metasurfaces. Thus, factors such as the number of metasurfaces and the distance between stacked metasurfaces may be determined according to a spectral resolution to be implemented.

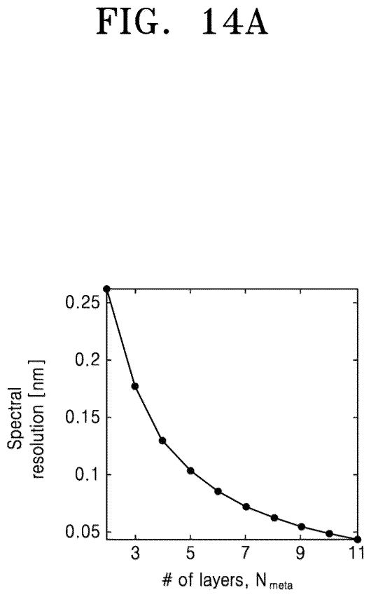

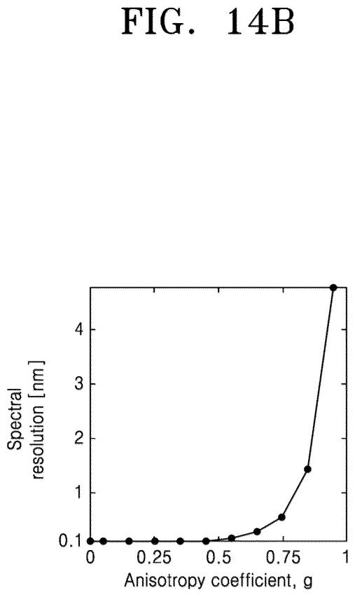

FIG. 14A is a graph illustrating a variation in spectral resolution with respect to the number of stacked metasurfaces when an inter-metasurface distance ΔL is about 200 μm, and an anisotropy coefficient g of a metasurface is about zero (ΔL=200 μm, g≈0). FIG. 14B is a graph illustrating a variation in spectral resolution with respect to an anisotropy coefficient of a metasurface when five metasurfaces are stacked at intervals ΔL of about 200 μm (Nₘₑₜₐ=5, ΔL≈200 μm).

As shown in FIGS. 14A and 14B, spectral resolution may be improved as the number Nₘₑₜₐ of stacked metasurfaces increases and the anisotropy coefficient g of the metasurface decreases. In addition, as the distance ΔL between stacked metasurfaces increases, spectral resolution may be improved. However, as the number Nₘₑₜₐ of stacked metasurfaces increases and the anisotropy coefficient g of the metasurface decreases, a speckle size may decrease. Thus, the number of stacked metasurfaces and the anisotropy coefficient g of the metasurface may be determined by considering the speckle size. That is, the number of stacked metasurfaces, the distance ΔL between metasurfaces, and the anisotropy coefficient g of metasurfaces may be selected to form a speckle pattern having an intended spectral resolution and an average speckle size that is greater than the pixel size of the light-receiving sensor 11, for example, greater than twice the pixel size of the light-receiving sensor 11.

In addition, a speckle pattern may be predicted through the design of random metasurfaces and a simulation thereof, random metasurfaces may be designed and a speckle pattern may be measured by a nano-processing method and an optical holography method. Therefore, reliability in design and fabrication may be evaluated by comparing a measured speckle pattern and a simulated speckle pattern.

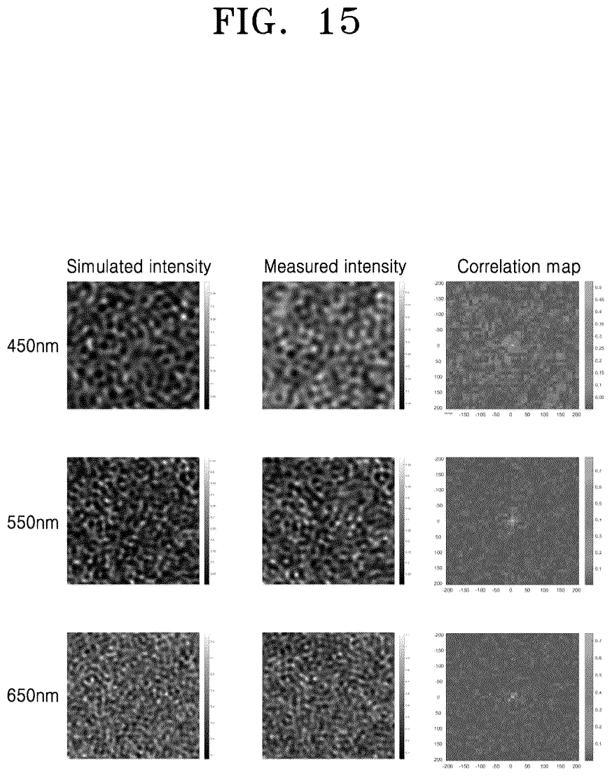

FIG. 15 is a diagram exemplarily illustrating results of comparison between speckle pattern measurements and speckle pattern simulations for a single random metasurface. As shown in FIG. 15, a measured intensity distribution and a simulated intensity distribution of a speckle pattern have a high correlation of at least 0.5 to a maximum of 0.8 even though the correlation somewhat varies according to wavelengths. From this, it could be understood that a speckle pattern produced by a stacked structure of the plurality of metasurfaces 100 may be predicted without a calibration process.

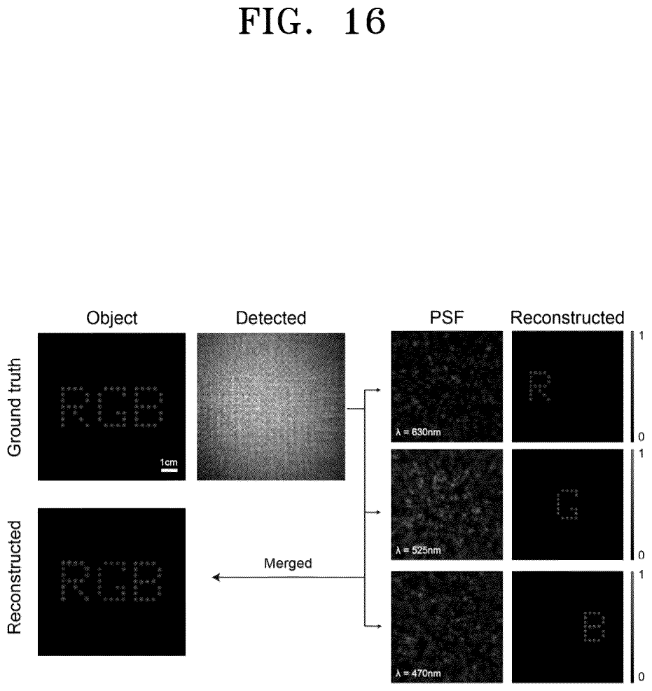

FIG. 16 is a diagram exemplarily illustrating a process of photographing an object and restoring object information by using the hyperspectral image sensor 10 according to an embodiment.

Referring to FIG. 16, information of a ground truth object detected using the hyperspectral image sensor 10 may be processed by the processor 50 with a point spread function (PSF) for each wavelengths λ of 630 nm, 525 nm, and 470 nm, and the information about the object for each wavelength may be reconstructed to restore into a reconstructed image for each wavelength. In addition, the information about the object for each wavelength may be merged to obtain a restored image that is reconstructed for the object. A performance of the hyperspectral image sensor 10 according to an embodiment, may be confirmed by comparing the ground truth object with the restored image that is reconstructed for the object.

According to the hyperspectral imaging system 1 including the hyperspectral image sensor 10 according to an embodiment, a deep neural network based restoration algorithm may be applied as a hyperspectral image restoration algorithm, and a hyperspectral image may be restored by setting a loss function as an optimization function for restoration, and repeatedly modifying object information to minimize it.

Hereinafter, an optical design example and speckle pattern simulation process for the hyperspectral image sensor 10 according to an embodiment and the hyperspectral imaging system 1 including the same will be described.

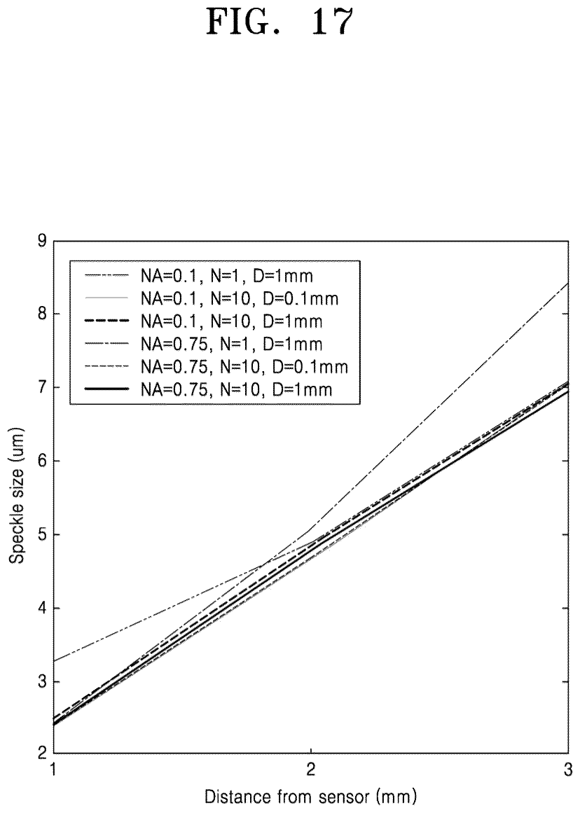

FIG. 17 is a graph illustrating a variation in speckle size according to the distance between a final metasurface and the light-receiving sensor 11. FIG. 17 shows speckle size simulation results according to a tailored numeral aperture NA of a metasurface, a number N of metasurfaces, a distance D between metasurfaces, and a distance Z between a final metasurface and a light-receiving sensor 11, in a system including a metasurface of about 200 μm in size and a light-receiving sensor 11 with a pixel size of about 1.67 μm.

As shown in FIG. 17, the speckle size of a speckle pattern formed on the sensing surface 11a of the light-receiving sensor 11 may vary according to the distance Z between the final metasurface (that is, the first metasurface 110) and the sensing surface 11a of the light-receiving sensor 11, and is substantially proportional to the distance between the final metasurface and the sensing surface 11a.

For example, the hyperspectral image sensor 10 according to an embodiment may be set to form a speckle pattern with a speckle size twice or more than the pixel size of the light-receiving sensor 11 to satisfy the Nyquist condition. For example, considering the simulation results shown in FIG. 17, when the hyperspectral image sensor 10 according to an embodiment has the light-receiving sensor 11 with a pixel size of about 1.67 μm, the distance Z between the final metasurface and the sensing surface 11a of the light-receiving sensor 11 may be set to about 1 μm or more to about 10 cm or less, for example, 100 μm, thereby satisfying the Nyquist condition, that is, speckle size=2×1.67 μm.

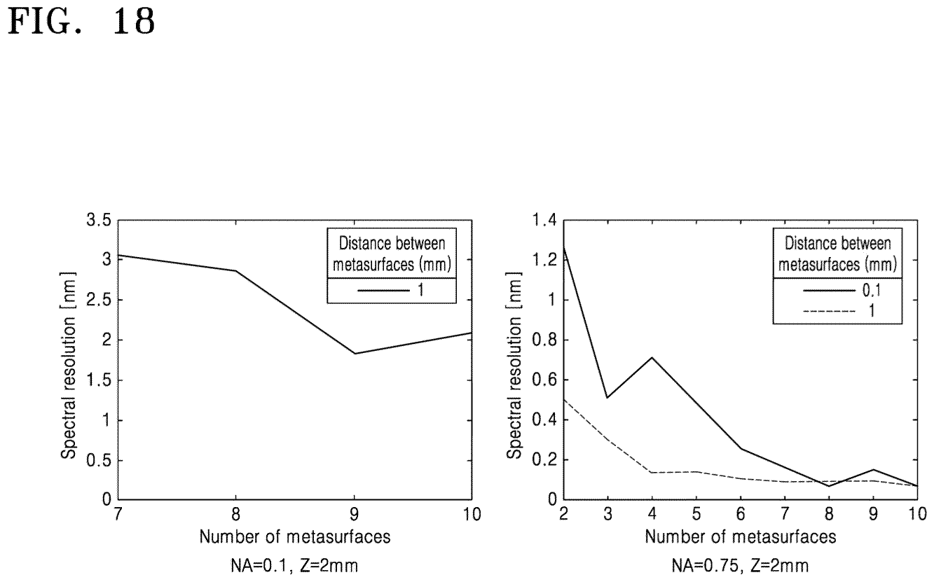

FIG. 18 exemplarily illustrates simulation result of spectral resolution according to a tailored numerical aperture (NA) of metasurfaces, the number N of metasurfaces, the distance D between metasurfaces, and the distance Z between the final metasurface and the light-receiving sensor 11. FIG. 18 shows simulation result for a system including a metasurface of about 200 μm in size and a light-receiving sensor 11 with a pixel size of about 1.67 μm.

In FIG. 18, a left graph shows a relationship between the number N of metasurfaces and spectral resolution when NA=0.1, Z=2 mm, and the distance D between metasurfaces is 1 mm. In FIG. 18, a right graph shows a relationship between the number N of metasurfaces and spectral resolution when NA=0.75, Z=2 mm, and the distance D between metasurfaces is 0.1 mm and 1 mm.

Comparing the left and right graphs when the distance D between metasurfaces is 1 mm, the left graph shows a spectral resolution of about 1.5 nm to about 3 nm when the number N of metasurfaces ranges from seven to ten, while the right graph shows a spectral resolution of about 0.2 nm or less when the number N of metasurfaces ranges from four to ten and a spectral resolution of 0.5 nm or less even when the number N of metasurfaces ranges from two to three. That is, it could be understood that the spectral resolution when NA=0.75 is applied is greatly improved compared to the spectral resolution when NA=0.1 is applied. In addition, the spectral resolution when NA=0.75 is applied is greatly improved even though the distance D between metasurfaces is as small as 1 mm, compared to the case in which NA=0.1 is applied and the distance D between metasurfaces is 1 mm. Furthermore, in the right graph of FIG. 18, comparing the spectral resolution when the distance D between metasurfaces is 0.1 mm with the spectral resolution when the distance D between metasurfaces is 1 mm, it could be understood that when six or more metasurfaces are stacked, the spectral resolution when the distance D between metasurfaces is 0.1 mm is close to the spectral resolution when the distance D between metasurfaces is 1 mm.

As shown in FIG. 18, the spectral resolution may greatly vary depending on the tailored numerical aperture NA, and may also vary depending on the distance D between metasurfaces and the number N of metasurfaces.

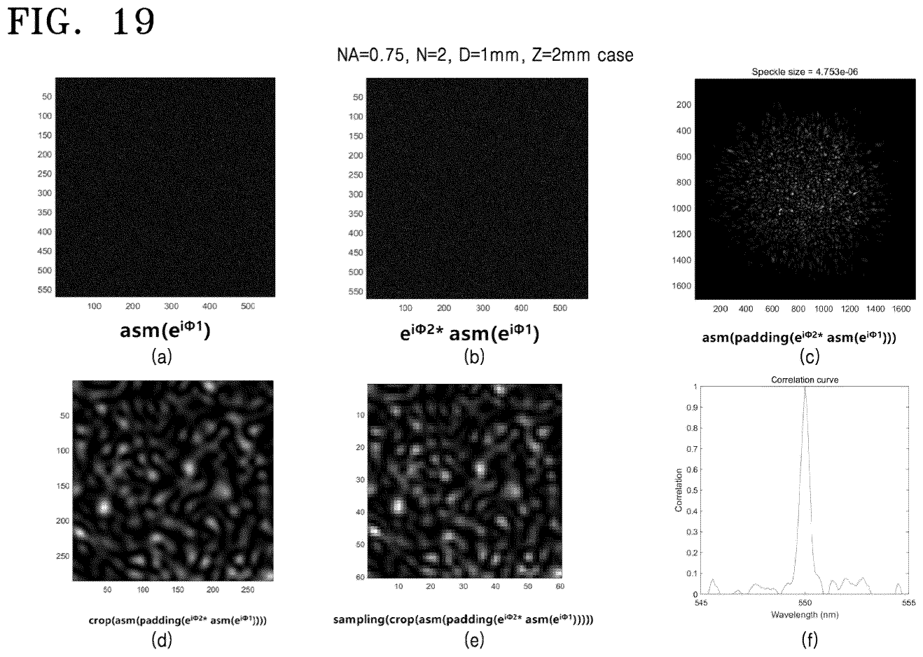

FIG. 19 is a diagram illustrating a process of simulating a speckle pattern when a plurality of metasurfaces are applied to the hyperspectral image sensor 10 according to an embodiment. FIG. 19 shows a process of simulating a speckle pattern according to a tailored numeral aperture NA, a number N of metasurfaces, a distance D between metasurfaces, and a distance Z between a final metasurface and a light-receiving sensor 11 in a system including a metasurface of about 200 μm in size and a light-receiving sensor 11 with a pixel size of about 1.67 μm.

Referring to FIG. 19, light passing through a plurality of metasurfaces while propagating a free space may be simulated by performing an angular spectrum method (ASM) on a field ei^{φ}1 with a phase φ of a tailored NA and then multiplying another field ei^{φ2} to the field ei^{φ1} under the conditions of NA=0.75, N=2, D=1 mm, and Z=2 mm. FIG. 19 shows a simulation process when two metasurfaces are applied.

FIG. 19(a) shows the application of the ASM to light passing through a first metasurface, that is, asm(ei^{φ1}). FIGS. 19(b) and (c) show the application of the ASM to light, ei^{φ2}*asm(ei^{φ1}), which passes through the first metasurface, travels through a free space, and then passes through a second metasurface. As shown in FIG. 19(c), results of a speckle pattern simulation may be obtained with respect to a final metasurface, for example, the second metasurface by performing zero padding on a field and then the ASM to the field (asm(padding(ei^{φ2}*asm(ei^{φ1})))).

In addition, as shown in (d), (e) and (f) of FIG. 19, a correlation curve may be obtained by cropping the final metasurface to half the size of the metasurface for the field to which the ASM is applied, and then using speckles sampled according to the pixel size of the light-receiving sensor 11 as a comparison object.

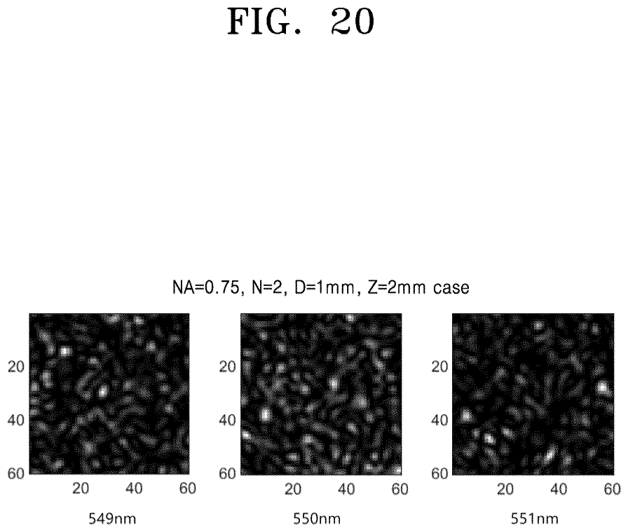

FIG. 20 is a diagram illustrating speckle pattern simulation results obtained by applying the speckle pattern simulation method according to the embodiment to FIG. 19 under the conditions of NA=0.75, N=2, D=1 mm, and Z=2 mm. FIG. 20 shows that different speckle patterns are formed at wavelengths of 549 nm, 550 nm, and 551 nm, respectively and from this, it may be confirmed that the hyperspectral image sensor 10 with a spectral resolution of 1 nm or less and the hyperspectral imaging system 1 applying the hyperspectral image sensor 10 may be implemented.

The above description is about optical design examples and speckle pattern simulations processes for implementing the hyperspectral image sensor 10 capable of capturing high-resolution hyperspectral images and the hyperspectral imaging system 1 including the hyperspectral image sensor 10 when applying the light-receiving sensor 11 with NA=0.75, Z=2 mm, a pixel size of 1.67 μm, but these numerical limitations are for illustrative purposes only, and embodiments are not limited thereto.

For example, the hyperspectral image sensor 10 and the hyperspectral imaging system 1 including the hyperspectral image sensor 10 may be designed to acquire high-resolution hyperspectral images even for different tailored numeral aperture NA, different distance between metasurfaces, and different pixel size of the light-receiving sensor 11.

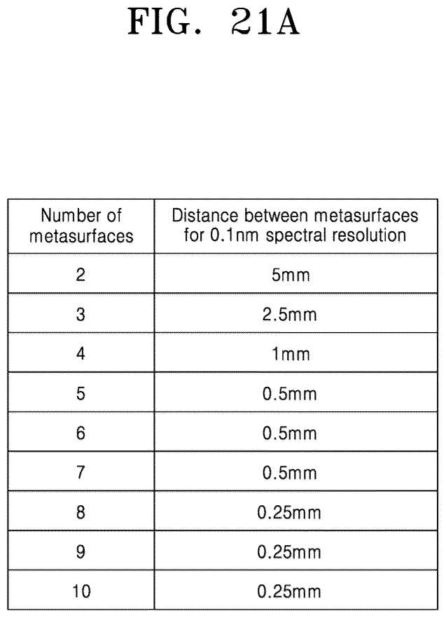

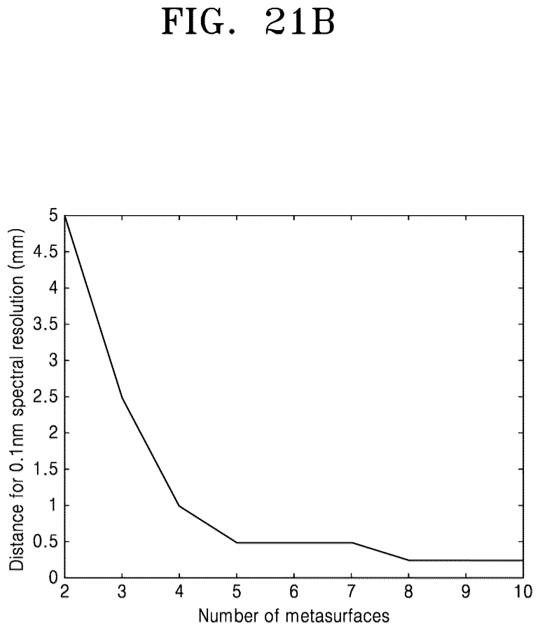

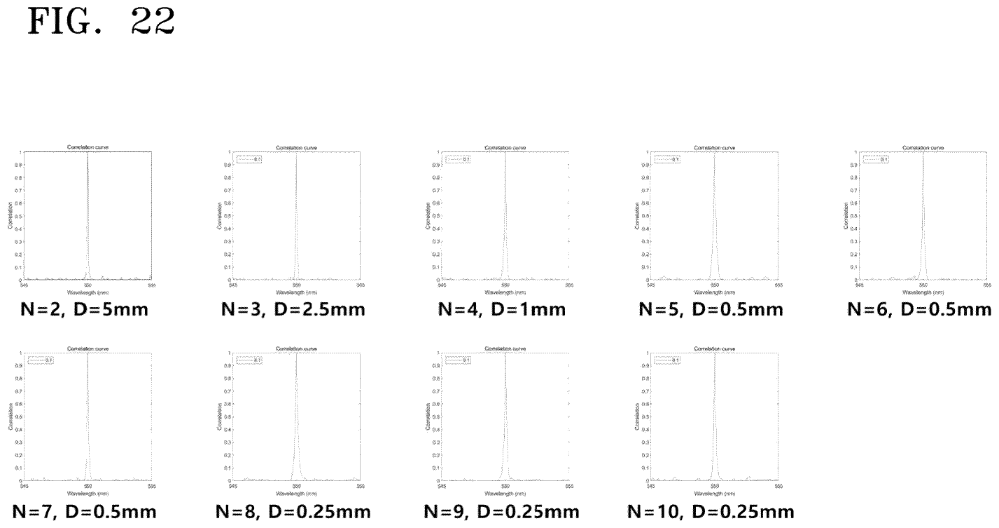

According to embodiments, when spectral resolution is defined using the fact that a speckle pattern varies according to wavelengths, the number of metasurfaces and the distance between metasurfaces in the hyperspectral image sensor 10 according to an embodiment and the hyperspectral imaging system 1 including the hyperspectral image sensor 10 may be determined as exemplarily illustrated in FIGS. 21A, 21B, 22, 23A, 23B, and 24 to implement a set spectral resolution. FIGS. 21A, 21B, 22 23A, 23B, and 24 exemplarily show results of simulations performed for a system including metasurfaces with a tailored NA of 0.1, and the light-receiving sensor 11 with a pixel size of about 1 μm.

FIGS. 21A and 21B exemplarily show the number N of metasurfaces and the distance D between metasurface as parameters for implementing a spectral resolution of about 0.1 nm when the spectral resolution is defined using the fact that speckles are differently formed according to wavelengths. FIG. 22 shows correlation curves of parameters, that is, the number N of metasurfaces and the distance D between metasurfaces for realizing a spectral resolution of 0.1 nm as shown in FIGS. 21A and 21B.

As exemplarily shown in FIGS. 21A, 21B, and 22, the hyperspectral image sensor 10 according to an embodiment and the hyperspectral imaging system 1 including the hyperspectral image sensor 10 may implement a spectral resolution of about 0.1 nm by selecting the number N of metasurfaces and the distance D between metasurfaces.

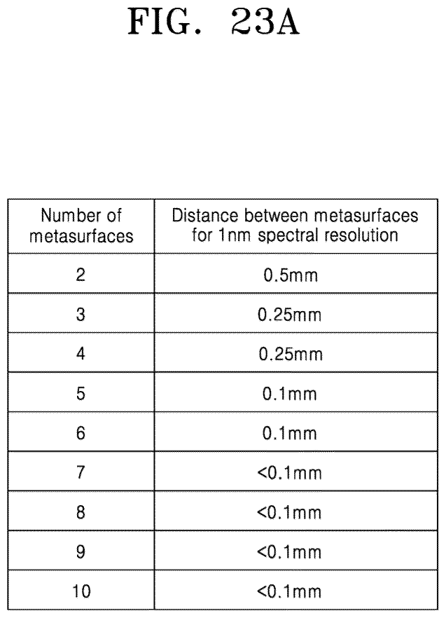

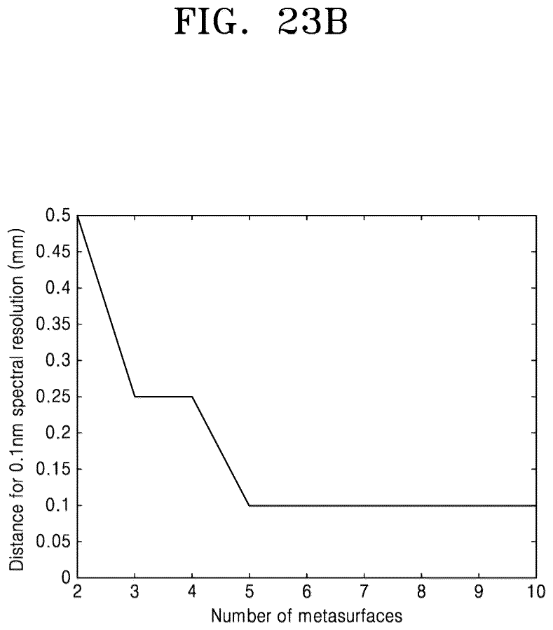

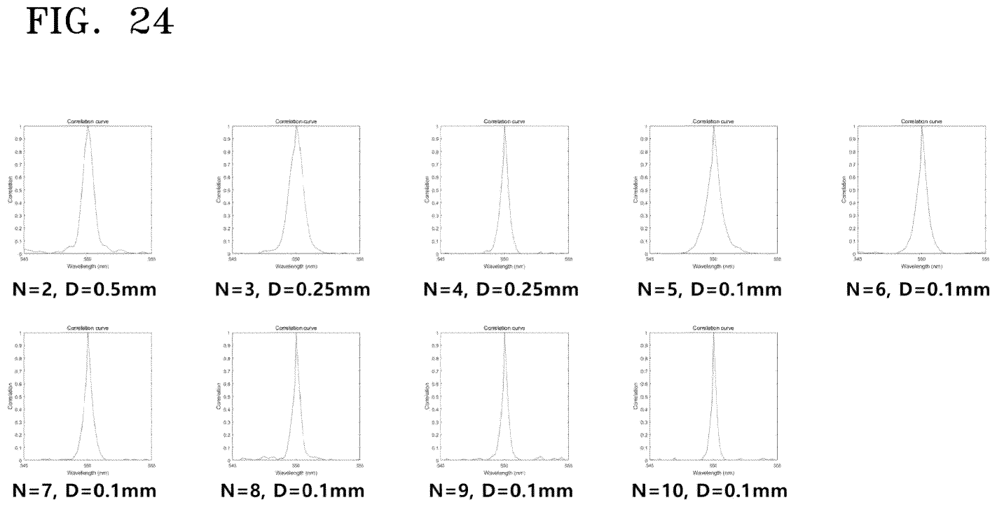

FIG. 23A and 23B exemplarily show the number of metasurfaces and the distance D between metasurface as parameters for implementing a spectral resolution of about 1 nm when the spectral resolution is defined using the fact that speckles are differently formed according to wavelengths. FIG. 24 shows correlation curves of parameters, that is, the number N of metasurfaces and the distance D between metasurfaces for realizing a spectral resolution of about 1 nm as shown in FIGS. 23A and 23B.

As exemplarily shown in FIGS. 23A, 23B, and 24, the hyperspectral image sensor 10 according to an embodiment and the hyperspectral imaging system 1 including the hyperspectral image sensor 10 may implement a spectral resolution of about 1 nm by selecting the number N of metasurfaces and the distance D between metasurfaces.

As described above, a specific spectral resolution may be obtained by designing the stacked structure of the metasurfaces 100.

The hyperspectral image sensor 10 according to the above-described embodiment and the hyperspectral imaging system 1 including the hyperspectral image sensor 10 may be employed in various high-performance optical devices or high-performance electronic devices. Examples of the electronic devices include smartphones, mobile phones, cellular phones, personal digital assistants (PDAs), laptop computers, personal computers (PCs), various portable devices, home appliances, security cameras, medical cameras, automobiles, Internet of Things (IoT) devices, and other mobile or non-mobile computing devices, but are not limited thereto.

In addition to the hyperspectral image sensor 10 and the hyperspectral imaging system 1 including the hyperspectral image sensor 10, the electronic devices may further include a processor such as an application processor (AP) configured to control the hyperspectral image sensor 10 and the hyperspectral imaging system 1, and may control a plurality of hardware or software components by executing an operating system or an application program through the processor, and may perform various data processing and calculation operations. The processor may further include a graphic processing unit (GPU) and/or an image signal processor. When the processor includes an image signal processor, image (or videos) acquired using the hyperspectral imaging system may be stored and/or output using the processor.

As described above, according to embodiments, the hyperspectral image sensor 10 and the hyperspectral imaging system 1 including the hyperspectral image sensor 10 may restore a hyperspectral image by separating overlapped speckle patterns into speckle patterns produced at individual positions and wavelengths. According to embodiments, a speckle pattern to be produced at an individual position and a wavelength by using metasurfaces may be predicted in advance, and using this information (spatio-spectral information), position and wavelength signals may be restored from overlapped speckle pattern images.

According to the hyperspectral image sensor 10 according to embodiments and the hyperspectral image sensor 1 including the hyperspectral image sensor 10, at least one of the metasurfaces 100 spaced apart from each other in the stacking direction thereof and having an array of meta-atoms 105 may be configured as a random metasurface with meta-atoms 105 arranged in a disorderly manner, to form a speckle pattern on the sensing surface 11a of the light-receiving sensor 11, thereby capable of controlling a spectral resolution by using the number of metasurfaces 100 and the distance between metasurfaces 100. Therefore, high-resolution hyperspectral images may be acquired by setting a spectral resolution according to controlling of the degree of limited disorder of the random metasurface, the number of stacked metasurfaces 100, and the distance between stacked metasurfaces 100.

While the above-described hyperspectral image sensor 10, and the hyperspectral imaging system 1 including the hyperspectral image sensor 10, a design example of the stacked structure of metasurfaces 100 for implementing a specific spectral resolution, and a speckle pattern simulation process have been described with reference to embodiments shown in the accompanying drawings, it is merely illustrative, and those skilled in the art will understand that various modifications and other equivalent embodiments may be made therein. Therefore, the embodiments described herein should be considered in a descriptive sense only and not for purposes of limitation. The scope of the disclosure is defined not by the above description but by the following claims, and all differences within equivalent ranges of the scope of the disclosure should be considered as being included in the scope of the disclosure.

What is claimed is:

1. A hyperspectral image sensor comprising:
a light-receiving sensor that is pixelated; and
a plurality of metasurfaces arranged in front of the light-receiving sensor apart from each other in a stacking direction, and each having an array of meta-atoms,
wherein at least one of the plurality of metasurfaces is a random metasurface in which the meta-atoms are arranged to exhibit a disordered phase delay distribution, and a speckle pattern is formed on a sensing surface of the light-receiving sensor by the plurality of metasurfaces.

2. The hyperspectral image sensor of claim 1, wherein, in the random metasurface, the meta-atoms are arranged in a disordered size distribution to exhibit random phase map information for incident plane wave, and
the random phase map is defined as phase delay values according to coordinates in a spatial domain.

3. The hyperspectral image sensor of claim 1, wherein the meta-atoms of the random metasurface have identical heights and irregular sizes.

4. The hyperspectral image sensor of claim 3, wherein the meta-atoms of the random metasurface are regularly positioned.

5. The hyperspectral image sensor of claim 1, wherein the meta-atoms of the random metasurface are regularly positioned and have irregular sizes.

6. The hyperspectral image sensor of claim 1, wherein at least one of a number of the plurality of metasurfaces and a distance between the metasurfaces is determined such that sizes of at least some of speckles of the speckle pattern are greater than a pixel size of the light-receiving sensor.

7. The hyperspectral image sensor of claim 6, wherein a degree of disorder of the plurality of metasurfaces is limited such that an average speckle size of the speckle pattern is greater than the pixel size of the light-receiving sensor.

8. The hyperspectral image sensor of claim 6, wherein a degree of disorder of the plurality of metasurfaces is limited such that an average speckle size of the speckle pattern is greater than twice the pixel size of the light-receiving sensor.

9. The hyperspectral image sensor of claim 6, wherein the plurality of metasurfaces comprise two to ten metasurfaces apart from each other.

10. The hyperspectral image sensor of claim 6, wherein a distance from the plurality of metasurfaces to the sensing surface of the light-receiving sensor is from 1 μm to 10 cm.

11. A hyperspectral imaging system comprising:
a hyperspectral image sensor comprising a light-receiving sensor that is pixelated and a plurality of metasurfaces that are arranged in front of the light-receiving sensor apart from each other in a stacking direction, and each have an array of meta-atoms, wherein at least one of the plurality of metasurfaces is a random metasurface in which the meta-atoms are arranged to exhibit a disordered phase delay distribution, and a speckle pattern is formed on a sensing surface of the light-receiving sensor by the plurality of metasurfaces;
a storage unit storing a random phase map information of the random metasurface; and
a processor configured to generate a hyperspectral image using the speckle pattern received by the light-receiving sensor and the random phase map information.

12. The hyperspectral imaging system of claim 11, wherein, in the random metasurface, the meta-atoms are arranged in a disordered size distribution to exhibit the random phase map information for incident plane wave, and
the random phase map is defined as phase delay values according to coordinates in a spatial domain.

13. The hyperspectral imaging system of claim 11, wherein the meta-atoms of the random metasurface have identical heights and irregular sizes.

14. The hyperspectral imaging system of claim 13, wherein the meta-atoms of the random metasurface are regularly positioned.

15. The hyperspectral imaging system of claim 11, wherein the meta-atoms of the random metasurface are regularly positioned and have irregular sizes.

16. The hyperspectral imaging system of claim 11, wherein at least one of a number of the plurality of metasurfaces and a distance between the metasurfaces is determined such that sizes of at least some of speckles of the speckle pattern are greater than a pixel size of the light-receiving sensor.

17. The hyperspectral imaging system of claim 16, wherein a degree of disorder of the plurality of metasurfaces is limited such that an average speckle size of the speckle pattern is greater than the pixel size of the light-receiving sensor.

18. The hyperspectral imaging system of claim 16, wherein a degree of disorder of the plurality of metasurfaces is limited such that an average speckle size of the speckle pattern is greater than twice the pixel size of the light-receiving sensor.

19. The hyperspectral imaging system of claim 16, wherein the plurality of metasurfaces comprise two to ten metasurfaces apart from each other.

20. The hyperspectral imaging system of claim 16, wherein a distance from the plurality of metasurfaces to the sensing surface of the light-receiving sensor is from 1 μm to 10 cm.
